(19) United States
(12) Patent Application Publication
(10) Pub. No.: US 2013/0027021 A1
(43) Pub. Date: Jan. 31, 2013

(54) CURRENT SENSOR

(71) Applicant: Kalyan P. Gokhale, New Berlin, WI (US)

(72) Inventor: Kalyan P. Gokhale, New Berlin, WI (US)

(73) Assignee: ABB INC., Cary, NC (US)

(21) Appl. No.: 13/192,783

(22) Filed: Jul. 28, 2011

(51) Int. Cl. G01R 15/20

(52) U.S. Cl. 324/117 R

(57) ABSTRACT

A current sensor is provided for measuring DC current in a primary conductor also carrying AC current. The current sensor includes a ferromagnetic core through which the primary conductor may extend. The core has a narrow air gap formed therein and a magnetic flux sensor is disposed in the air gap. A secondary winding is mounted to the core and has an impedance connected therein. The impedance has a value of substantially zero at one or more frequencies of the AC current. The impedance may be a short or an impedance source that includes a capacitor and an inductor.

### BACKGROUND OF THE INVENTION

This invention relates to sensors and, more particularly to current sensors for measuring DC current in a conductor also carrying AC current.

Current sensors for measuring DC current are known. One type of conventional current sensor 10 is shown in FIG. 1 and is known as an open loop Hall effect current sensor. The current sensor 10 includes a ferromagnetic core 12 having an air gap 14 with a Hall element 16 disposed therein for measuring magnetic flux. A primary conductor 18 extends through the center of the core 12 and carries current therethrough. If the primary conductor 18 is carrying both AC and DC current, the total primary current (Iₚᵣᵢ) can be represented as Iₚᵣᵢ=I_{ac}+I_{dc}. The flux density in the core 12 and in the air gap 14 is proportional to the total primary current Iₚᵣᵢ. Thus, the Hall element 16 produces a voltage Vo=Vo_{ac}+Vo_{dc} that is proportional to Iₚᵣᵢ.

If the AC current is significantly greater than the DC current in the primary conductor 18, then Vo_{dc}<<Vo_{ac}. In this case, an amplifier 20 with low pass filter characteristics is used to extract the signal of interest, Vo_{dc}. The amplifier 20 provides substantial gain to the DC component, Vo_{dc,} while attenuating the AC component, Vo_{ac}.

The foregoing system has a number of disadvantages when the AC current is significantly greater than the DC current in the primary conductor 18. One disadvantage is the size of the air gap 14. Since the magnetic flux produced by I_{ac} is many times greater than the flux produced by I_{dc}, the air gap 14 must be large so that the core 12 does not saturate due to the large amount of flux produced by I_{ac}. The large size of the air gap 14 reduces the basic sensitivity of the sensor 10, as defined as sensor output voltage per unit of the primary current. Another disadvantage is the large amount of AC component of flux passing through the core 12, which produces core losses and heat in the core 12. Still another disadvantage is that the amplifier 20 used to extract and amplify the small signal Vo_{dc}, also amplifies error components (e.g. offset voltage) of the Hall element 16, thereby reducing the overall accuracy of the measurement of I_{dc}.

Based on the foregoing, there is a need in the art for an improved current sensor for measuring DC current in a conductor also carrying AC current.

### SUMMARY OF THE INVENTION

In accordance with the present invention, a current sensor is provided for measuring DC current in a primary conductor also carrying AC current. The current sensor includes a ferromagnetic core through which the primary conductor may extend. The core has an air gap formed therein. A magnetic flux sensor is disposed in the air gap. A secondary winding is mounted to the core. The secondary winding has an impedance connected therein. The impedance has a value of substantially zero at one or more frequencies of the AC current. The air gap has a width less than twice the thickness of the magnetic flux sensor.

Also provided in accordance with the present invention is an inverter system for connection by one or more primary conductors to a utility network. The inverter system includes an inverter for connection by the one or more primary conductors to the utility network. The inverter system also includes one or more current sensors for connection to the one or more primary conductors. Each of the current sensors has the construction described above.

### BRIEF DESCRIPTION OF THE DRAWINGS

The features, aspects, and advantages of the present invention will become better understood with regard to the following description, appended claims, and accompanying drawings where:

FIG. 1 shows a prior art current sensor;

FIG. 2 shows a utility interactive inverter system having one or more current sensors embodied in accordance with the present invention;

FIG. 3 shows a side view of a first current sensor constructed in accordance with a first embodiment of the present invention;

FIG. 4 shows a top view of the first current sensor;

FIG. 5 shows a side view of a second current sensor constructed in accordance with a second embodiment of the present invention;

FIG. 6 shows a side view of the second current sensor having a first construction;

FIG. 7 shows a response of the second current sensor with the first construction for different frequencies of a primary current;

FIG. 8 shows a side view of the second current sensor having a second construction; and

FIG. 9 shows a response of the second current sensor with the second construction for different frequencies of a primary current.

### DETAILED DESCRIPTION OF ILLUSTRATIVE EMBODIMENTS

It should be noted that in the detailed description that follows, identical components have the same reference numerals, regardless of whether they are shown in different embodiments of the present invention. It should also be noted that in order to clearly and concisely disclose the present invention, the drawings may not necessarily be to scale and certain features of the invention may be shown in somewhat schematic form.

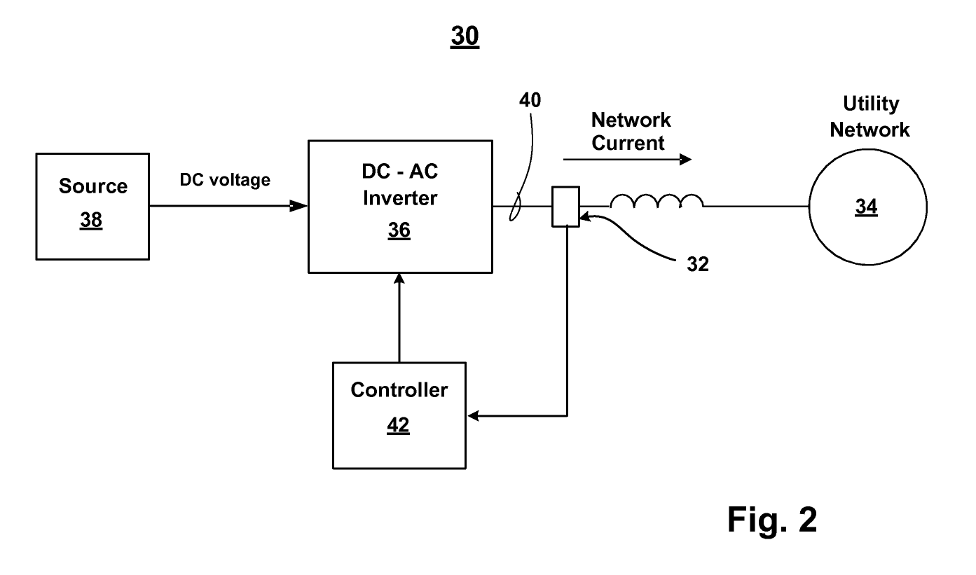

Referring now to FIG. 2, there is shown a utility interactive inverter system 30 that utilizes one or more current sensors 32 embodied in accordance with the present invention. The inverter system 30 has particular utility for tying renewable energy sources, like wind turbines, fuel cells, and photovoltaic solar cells, to an AC utility network 34. The inverter system 30 comprises an inverter 36 that receives DC voltage from a DC source 38 (such as a renewable energy source) and converts the DC voltage to an AC current. The inverter 36 may be single-phase or three-phase and is operable to perform power conversion from DC to AC at the utility frequency (e.g. 50 or 60 Hz) and regulate the power fed into the utility network 34. The inverter 36 includes a plurality of power electronic switches, such as insulated gate bipolar transistors (IGBTs). The inverter 36 is connected to the utility network 34 by one or more lines or primary conductors 40 (depending on the number of phases). A current sensor 32 is mounted to each primary conductor 40 and is operable to accurately measure the DC current therein. A microprocessor-based current controller 42 is connected to the current sensor(s) 32 to receive the DC current measurement(s) therefrom. The current controller 42 is connected to the inverter 36 and is operable to control the switches in the inverter 36.

The inverter system 10 is classified as a transformer-less system because no isolation transformer is used between the inverter 36 and the utility network 34. When such a transformer-less system is used, utility regulations typically require that the current fed into the utility network must be primarily AC and the amount of the DC current must be limited to a very low level, usually to less than 1% of the rating of the system. The current controller 42 uses the DC current measured by the current sensor(s) 32 to appropriately adjust the switching pattern of the switches in the inverter 36 so that the amount of DC current entering the utility network 34 is almost zero, i.e., about 0.1 percent of the total current provided to the utility network 34 is DC current.

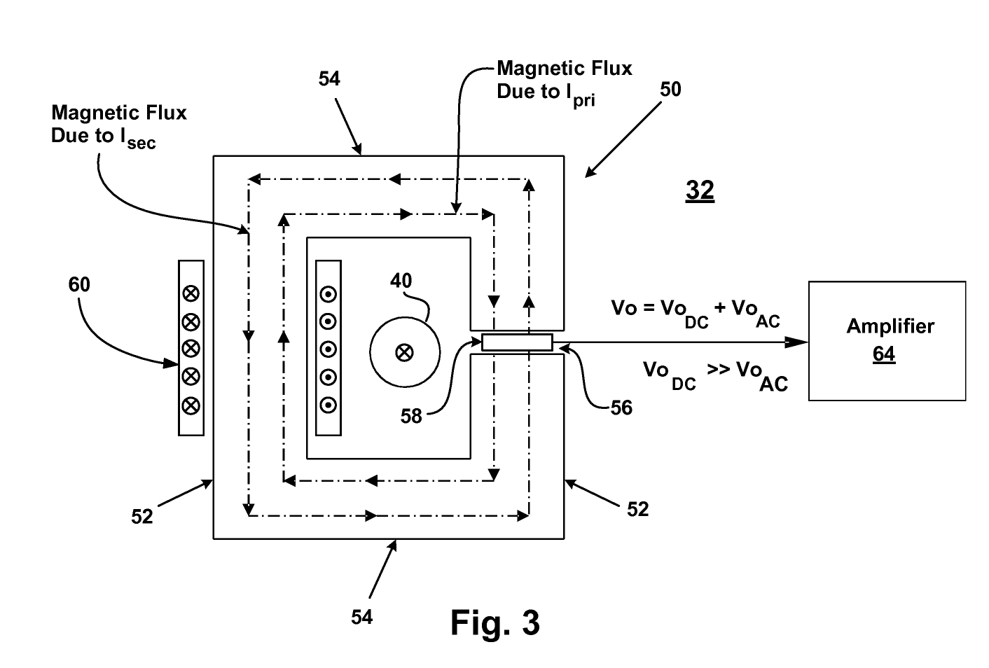

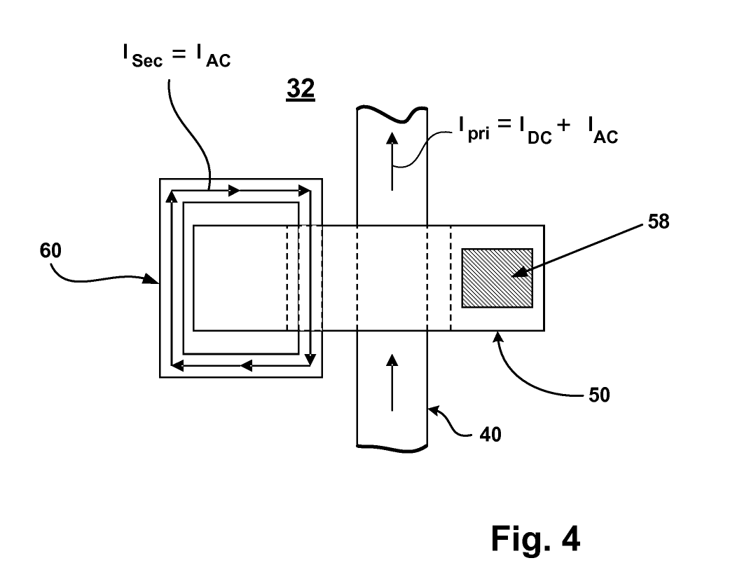

Referring now to FIGS. 3 and 4, there is shown a more detailed view of a current sensor 32, which is constructed so as to be responsive primarily to the DC component (I_{dc}) of the total primary current (Iₚᵣᵢ) in a primary conductor 40, while rejecting the AC component (I_{ac}). The current sensor 32 comprises a core 50 comprised of a ferromagnetic material, such as Mu-metal (an alloy comprising about 75% nickel, 15% iron, plus copper and molybdenum), silicon steel and/or amorphous magnetic metal. The core 50 may be rectangular and have a pair of spaced apart legs 52 and a pair of yokes 54 secured to opposing ends of the legs, respectively. Alternately, the core 50 may be toroidal in shape. The primary conductor 40 extends through the core 50, such as between the legs 52 and between the yokes 54. A portion of the core 50 (such as one of the legs 52) has an air gap 56 formed therein. A magnetic flux sensor 58, such as a Hall element, is disposed in the air gap 56. The air gap 56 is very small, having a width (e.g., in the direction of the leg 52) less than twice the thickness of the magnetic flux sensor 58, more particularly less than 1.5 times the thickness of the magnetic flux sensor 58. In some embodiments, the air gap 56 may be only slightly greater than the thickness of the magnetic flux sensor 58. A secondary winding 60 is wound around the leg 52, opposite the leg 52 with the air gap 56 formed therein. The secondary winding 60 is composed of one or more turns of a conductor composed of a metal, such as copper. A single turn of the conductor has been found to work especially well and is assumed to be present in the following description. Ends of the conductor are connected together so as to short the secondary winding 60.

An amplifier 64 with low pass filter characteristics is used to extract the signal of interest, Vo_{dc}. The amplifier 64 provides gain to the DC component, Vo_{dc,} while attenuating the AC component, Vo_{ac}.

The operation of the sensor 32 will now be described. The primary current Iₚᵣᵢ=I_{ac}+I_{dc} in the primary conductor 40 establishes AC and DC components of the magnetic flux proportional to the I_{ac} and I_{dc}, respectively. The AC portion of the magnetic flux induces AC voltage in the secondary winding 60. Since it is a shorted winding, the induced current in the secondary winding 60 (I_{sec}) is substantially equal in magnitude, but opposite in polarity of the AC current component in the primary conductor 40 (I_{ac}). The net result is the AC component of the magnetic flux produced by I_{ac} is substantially nulled by the magnetic flux produced by the induced secondary current I_{sec}. As a result, the flux in the core 50, as experienced by the magnetic flux sensor 58 is primarily due to DC current. This is because the flux in the air gap 56 is only comprised of flux due to the DC component (I_{dc}) and a small portion of AC flux due to the AC component (I_{ac}) that is not canceled out by the flux produced by the induced secondary current (I_{sec}).

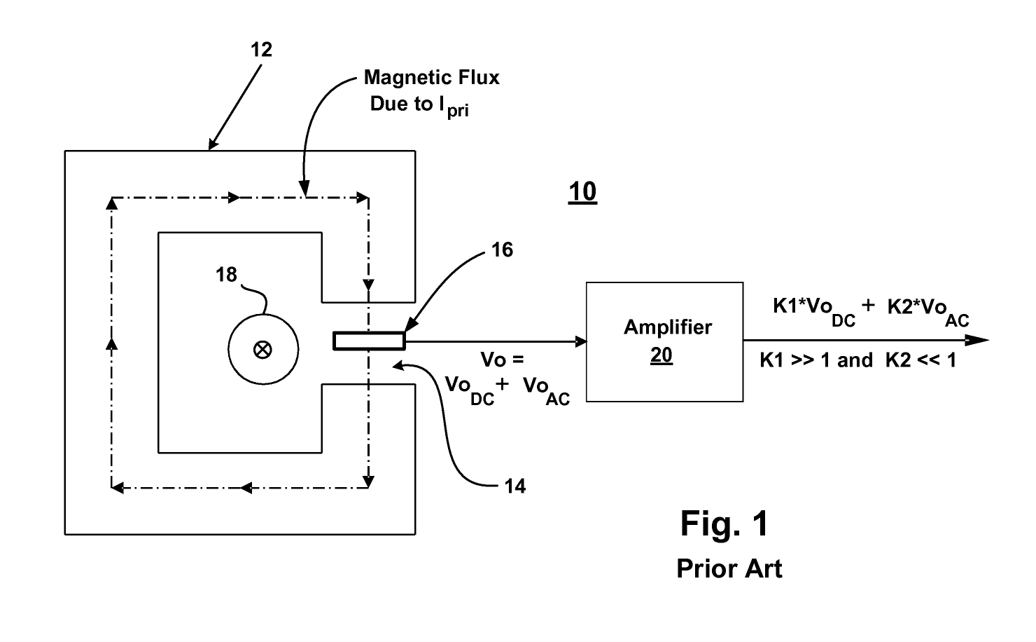

Since the core 50 does not have to carry a large amount of AC flux due to I_{ac}, there is no danger of saturating the core 50. As a result, the air gap 56 can be reduced substantially as compared to the air gap 14 used in the prior art sensor 10 shown in FIG. 1. In this regard, it is noted that the required size of the air gap is proportional to the “net” primary current (AC plus DC) in the primary conductor 40 responsible for the magnetic flux in the core 50. As a result of the shorted secondary winding 60, the net primary current that produces the magnetic flux can be as much as 20 times smaller than that produced in the prior art sensor 10, thereby permitting the air gap 56 to be drastically reduced in size. As a result, the sensitivity of the current sensor 32 is substantially increased. The output, Vo, of the magnetic flux sensor 58 primarily consists of Vo_{dc}, a signal proportional to I_{dc} but at a relatively high magnitude due to the increased sensitivity of the current sensor 32. A very small amount of Vo_{ac}, due to residual AC flux in the core 50, also exists in Vo. Since the sensitivity of the current sensor 32 is much higher, the amplification requirement to extract Vo_{dc} is substantially reduced, thus reducing the inaccuracies due to the offset voltage and offset voltage drift due to ambient temperature changes.

As described above, the current sensor 32 allows substantially only DC magnetic flux in the core 50 and substantially cancels the AC component of magnetic flux, thereby making the current sensor 32 responsive to DC current rather than AC current. This is accomplished by providing a secondary winding 60 whose output is shorted. A variation of this technique is now presented where the selectivity of a current sensor can be tailored as needed for a specific application.

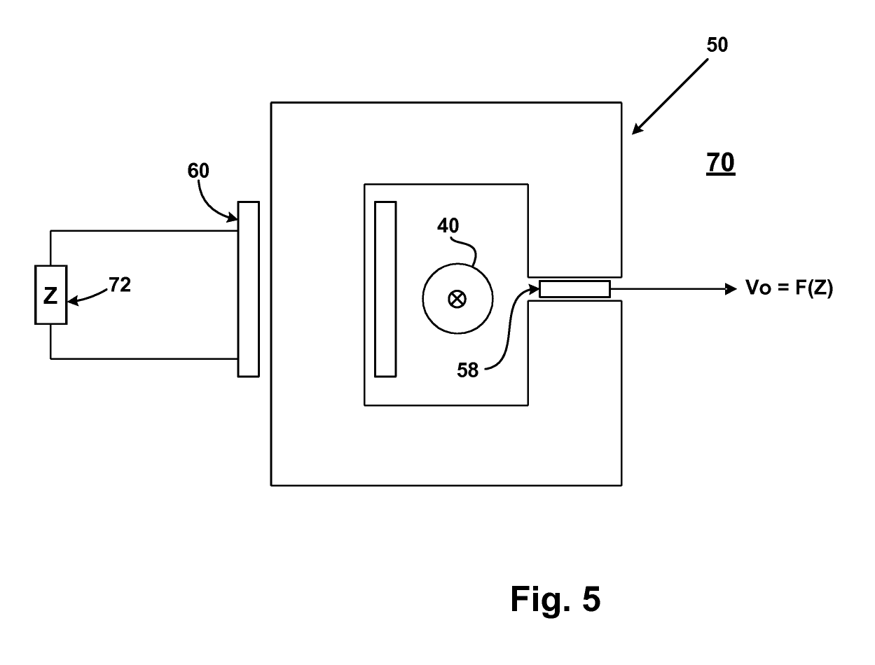

Referring now to FIG. 5, there is shown a current sensor 70 that has substantially the same construction as the current sensor 32, except the secondary winding 60 is not shorted. Instead, an impedance branch 72 is connected at the output of the secondary winding 60. In addition, the secondary winding 60 typically has a plurality of turns. The impedance branch 72 can be constructed using a combination of linear or nonlinear passive components such as resistors, inductors and capacitors and active components such as operational amplifiers, transistors, diodes etc. When the impedance branch 72 has an impedance (Z)=0, the current sensor 70 may be viewed as being substantially equivalent to the current sensor 32.

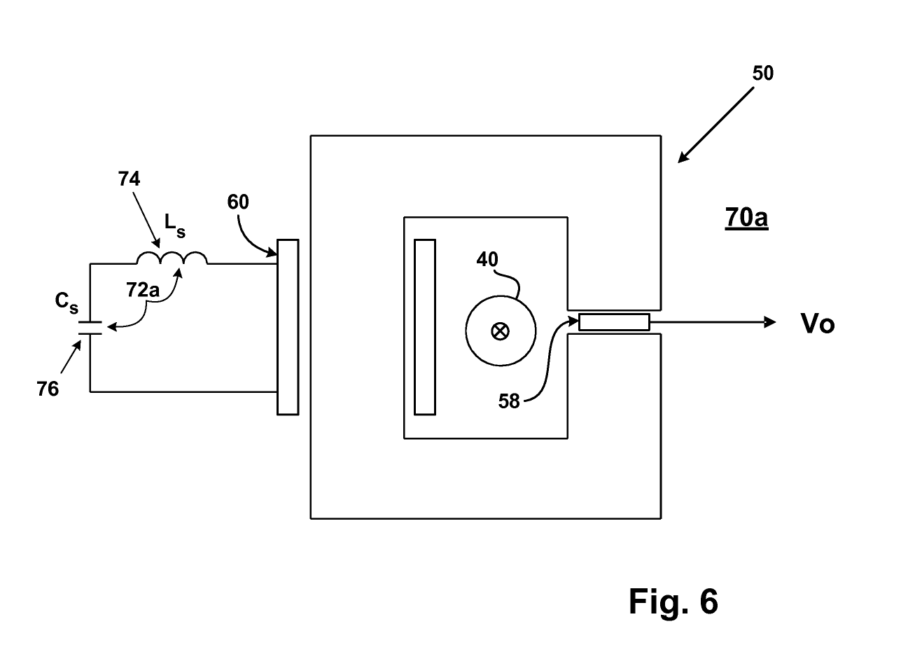

The current sensor 70 can be constructed to have different frequency selectivity. Referring now to FIG. 6, there is shown a first such construction, wherein the current sensor has the reference numeral 70a to distinguish it from other constructions. In the current sensor 70a, the impedance branch 72a comprises a series resonant circuit consisting of the series connection of an inductor 74 (having an inductance Lₛ) and a capacitor 76 (having capacitance Cₛ) with resonant frequency

$${F}_{s} = \frac{1}{2 π \sqrt{{L}_{s} {C}_{s}}} .$$

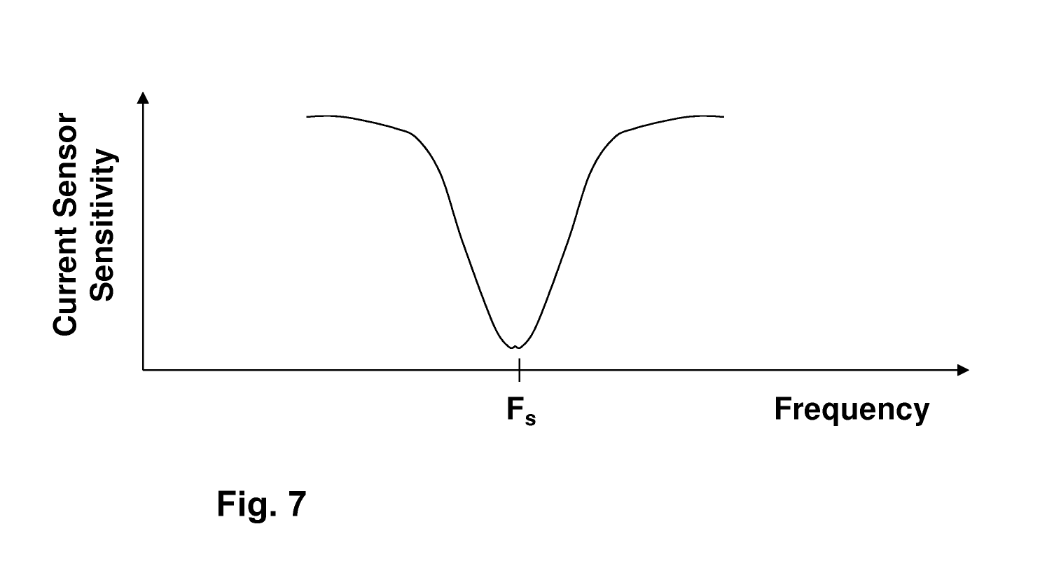

This circuit offers close to zero impedance at the resonant frequency Fₛ and high impedance at other frequencies. The magnetic flux produced by the AC component (I_{ac}) of the primary current (Iₚᵣᵢ) at the resonant frequency Fₛ is canceled by the secondary current (I_{sec}) due to the very low impedance of the series resonant circuit at the resonant frequency Fₛ. Since the magnetic flux produced by the AC component at the resonant frequency Fₛ is largely canceled out, the sensitivity (voltage per unit of primary current) of the current sensor 70a is greatly reduced at Fₛ. In other words, the current sensor 70a is sensitive (responsive) to all frequencies except at Fₛ, as shown in FIG. 7.

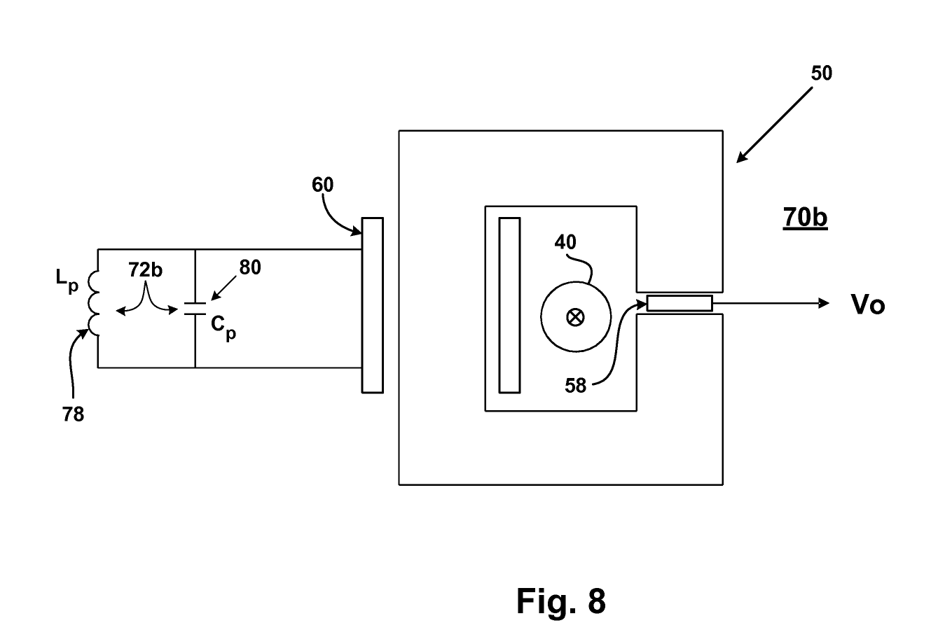

Referring now to FIG. 8, there is shown a current sensor 70b having an impedance branch 72b that comprises a parallel resonant circuit consisting of the parallel connection of an inductor 78 (having inductance Lₚ) and a capacitor 80 (having capacitance Cₚ) with a resonant frequency

$${F}_{p} = \frac{1}{2 π \sqrt{{L}_{p} {C}_{p}}} .$$

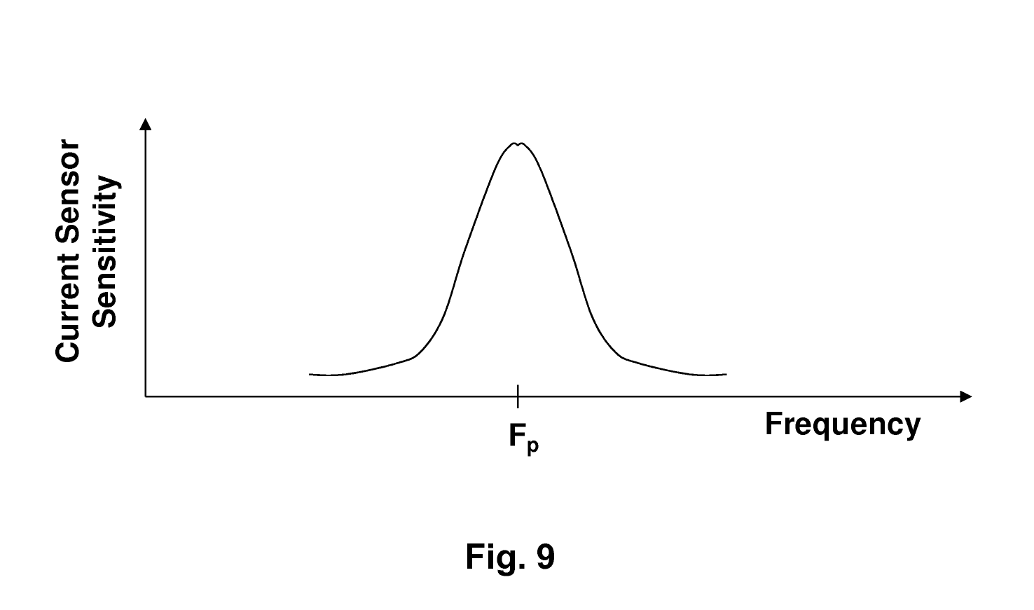

This circuit offers very high impedance at the resonant frequency Fₚ and low impedance at other frequencies. The magnetic flux produced by the AC component (I_{ac}) of the primary current (Iₚᵣᵢ) at the resonant frequency Fₚ is not canceled by the secondary current (I_{sec}) because it is not allowed to flow due to the very high impedance of the parallel resonant circuit at the resonant frequency Fₚ. Thus, the current sensor 70b is sensitive (responsive) to Fₚ and not sensitive (responsive) to frequencies below and above Fₚ, as shown in FIG. 9.

The current sensors 70a,b illustrate how frequency selectivity can be achieved for a sensor's response. By choosing an appropriate circuit for the impedance branch 72, the frequency responsiveness of the current sensor 70 can be tailored to meet the impedance versus frequency requirements.

It is to be understood that the description of the foregoing exemplary embodiment(s) is (are) intended to be only illustrative, rather than exhaustive, of the present invention. Those of ordinary skill will be able to make certain additions, deletions, and/or modifications to the embodiment(s) of the disclosed subject matter without departing from the spirit of the invention or its scope, as defined by the appended claims.

What is claimed is:

1. A current sensor for measuring DC current in a primary conductor also carrying AC current, the current sensor comprising:
a ferromagnetic core through which the primary conductor may extend, the core having an air gap formed therein;
a magnetic flux sensor disposed in the air gap;
a secondary winding mounted to the core, the secondary winding have an impedance connected therein, the impedance having a value of substantially zero at one or more frequencies of the AC current; and
wherein the air gap has a width less than twice the thickness of the magnetic flux sensor.

2. The current sensor of claim 1, wherein the impedance comprises a short in which ends of the secondary winding are connected together.

3. The current sensor of claim 2, wherein the secondary winding has a single turn.

4. The current sensor of claim 1, wherein the air gap has a width less than one and a half times the thickness of the magnetic flux sensor.

5. The current sensor of claim 1, wherein the core comprises a pair of spaced apart legs and a pair of spaced-apart yokes, a first one of the yokes extending across first ends of the legs and a second one of the yokes extending across a second one of the legs, and wherein the air gap is formed in one of the legs.

6. The current sensor of claim 1, wherein the core is toroidal.

7. The current sensor of claim 1, wherein the impedance comprises a circuit having at least one device selected from the group consisting of a resistor, an inductor, a capacitor, an operational amplifier, a transistors and a diode.

8. The current sensor of claim 7, wherein the circuit comprises an inductor and a capacitor.

9. The current sensor of claim 8, wherein the inductor and the capacitor are connected in series.

10. The current sensor of claim 8, wherein the inductor and the capacitor are connected in parallel.

11. The current sensor of claim 1, wherein the magnetic flux sensor is a Hall element.

12. An inverter system for connection by one or more primary conductors to a utility network, the inverter system comprising:
an inverter for connection by the one or more primary conductors to the utility network; and
one or more current sensors for connection to the one or more primary conductors, respectively, each current sensor comprising:
a ferromagnetic core through which one of the primary conductors may extend, the core having an air gap formed therein;
a magnetic flux sensor disposed in the air gap;
a secondary winding mounted to the core, the secondary winding have an impedance connected therein, the impedance having a value of substantially zero at one or more frequencies of the AC current; and
wherein the air gap has a width less than twice the thickness of the magnetic flux sensor.

13. The inverter system of claim 12, further comprising a controller for controlling the operation of the inverter based on the DC current(s) measured by the one or more current sensors.

14. The inverter system of claim 13, wherein the controller is operable to control the inverter such that 0.1 percent or less of the current output from the inverter is DC current.

15. The inverter system of claim 12, wherein the inverter is a three-phase inverter, the one or more primary conductors comprise three primary conductors and the one or more current sensors comprises three current sensors connected to the three primary conductors, respectively.

16. The inverter system of claim 12, wherein the impedance comprises a short in which ends of the secondary winding are connected together.

17. The inverter system of claim 12, wherein the impedance comprises a circuit having at least one device selected from the group consisting of a resistor, an inductor, a capacitor, an operational amplifier, a transistors and a diode.

18. The inverter system of claim 17, wherein the circuit comprises an inductor and a capacitor.

19. The inverter system of claim 18, wherein the inductor and the capacitor are connected in series.

20. The inverter system of claim 18, wherein the inductor and the capacitor are connected in parallel.
